(19) United States
(12) Patent Application Publication
(10) Pub. No.: US 2020/0035782 A1
(43) Pub. Date: Jan. 30, 2020

(54) SEMICONDUCTOR STRUCTURE

(71) Applicants: UNITED MICROELECTRONICS CORP., Hsin-Chu City (TW); Fujian Jinhua Integrated Circuit Co., Ltd., Quanzhou City (CN)

(72) Inventors: Li-Wei Feng, Kaohsiung City (TW); En-Chiuan Liou, Tainan City (TW); Yu-Cheng Tung, Kaohsiung City (TW); Wei-Lun Hsu, Kaohsiung City (TW); Yu-Hsiang Hung, Tainan City (TW); Ming-Te Wei, Changhua County (TW); Le-Tien Jung, Hsinchu City (TW)

(21) Appl. No.: 16/116,859

(22) Filed: Aug. 29, 2018

(30) Foreign Application Priority Data
Jul. 27, 2018 (CN) 201810841826.9

(51) Int. Cl. H01L 49/02; H01L 27/02; H01L 29/94; H01G 4/01

(52) U.S. Cl. CPC H01L 28/91; H01G 4/01; H01L 29/94; H01L 27/0207

(57) ABSTRACT

The present invention provides a semiconductor structure including a substrate including a plurality of capacitor lower electrodes, the capacitor lower electrodes are arranged in a diamond array along a first direction and a second direction respectively, the first direction and the second direction are not perpendicular to each other. A supporting structure layer contacts at least parts of the capacitor lower electrodes, wherein the supporting structure layer includes a plurality of triangular openings, and the three corners of each triangular opening are overlapped with three adjacent capacitor lower electrodes respectively.

### BACKGROUND OF THE INVENTION

### 1. Field of the Invention

The present invention relates to the field of semiconductors, and more particularly to a semiconductor structure having a cylindrical capacitor structure and a supporting structure layer.

### 2. Description of the Prior Art

As semiconductor devices have been highly integrated, an area of a unit cell may be decreased. Therefore, in order to avoid decreased capacitance of a capacitor, the capacitor may require a large effective surface area, e.g., a cylindrical shape. However, when the capacitor has a lower electrode having a high aspect ratio, the capacitor may be unstable. For example, fall down and contact adjacent capacitors, thereby causing damage and a leakage current therethrough.

### SUMMARY OF THE INVENTION

The present invention provides a semiconductor structure, the semiconductor structure includes a substrate comprising a plurality of capacitor lower electrodes, wherein the capacitor lower electrodes are arranged in a diamond array along a first direction and a second direction respectively, and wherein the first direction and the second direction are not perpendicular to each other, and a supporting structure layer contacting at least parts of the capacitor lower electrodes, wherein the supporting structure layer comprises a plurality of triangular openings, and wherein the three corners of each triangular opening are overlapped with three adjacent capacitor lower electrodes respectively.

The present invention further provides a semiconductor structure, the semiconductor structure includes a substrate comprising a plurality of capacitor lower electrodes, wherein the capacitor lower electrodes are arranged in a diamond array along a first direction and a second direction respectively, and wherein the first direction and the second direction are not perpendicular to each other, and a supporting structure layer contacting at least parts of the capacitor lower electrodes, wherein the supporting structure layer comprises a plurality of isosceles trapezoidal openings, and wherein the four corners of each isosceles trapezoidal openings are overlapped with four different capacitor lower electrodes respectively.

The present invention further provides a semiconductor structure, the semiconductor structure includes a substrate comprising a plurality of capacitor lower electrodes, wherein the capacitor lower electrodes are arranged in a diamond array along a first direction and a second direction respectively, and wherein the first direction and the second direction are not perpendicular to each other, and a supporting structure layer contacting at least parts of the capacitor lower electrodes, wherein the supporting structure layer comprises a plurality of rectangular openings, and three capacitor lower electrodes that do not overlap the rectangular openings are disposed between any two adjacent rectangular openings, wherein the three capacitor lower electrodes are not arranged in a straight line.

The present invention provides a semiconductor structure having cylindrical capacitor electrodes and a supporting structure layer. The supporting structure layer comprises openings of different shapes and different arrangements. By changing the shape and arrangement of the openings, to achieve the uniform effect of the overall force of the supporting structure layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 3 are schematic cross-sectional views showing a semiconductor structure having a supporting structure and cylindrical capacitor lower electrodes.

FIG. 4 is a top plan view showing the semiconductor structure of the first preferred embodiment of the present invention.

FIG. 5 is a top plan view showing a semiconductor structure in accordance with a second preferred embodiment of the present invention.

FIG. 6 is a top plan view showing a semiconductor structure in accordance with a third preferred embodiment of the present invention.

FIG. 7 is a top plan view showing a semiconductor structure in accordance with a fourth preferred embodiment of the present invention.

FIG. 8 is a top plan view showing a semiconductor structure in accordance with a fifth preferred embodiment of the present invention.

FIG. 9 is a top plan view showing a semiconductor structure of a sixth preferred embodiment of the present invention.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

Please note that the figures are only for illustration and the figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

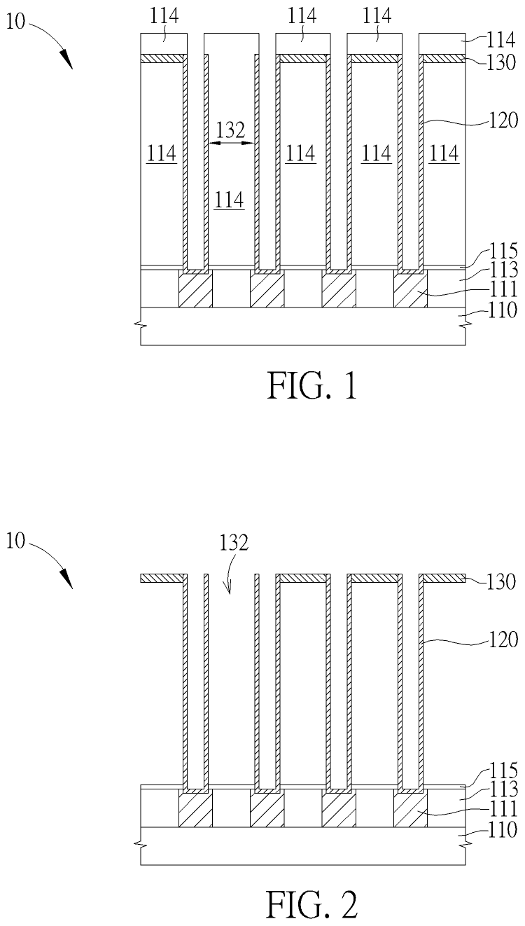

Please refer to FIG. 1 to FIG. 3, which shows a schematic cross-sectional view of a semiconductor structure having a supporting structure and a cylindrical capacitor. As shown in FIG. 1, a semiconductor device 10 includes a substrate 110 and an insulating layer 113 disposed on the substrate 110. A plurality of contact plugs 111 may be buried in the insulating layer 113. A plurality of cylindrical capacitor lower electrodes 120 (i.e., a plurality of storage node electrode) may be disposed in the insulating layer 113 and in an insulating layer 114. Besides, the capacitor lower electrodes 120 may be electrically connected to respective ones of the contact plugs 111. An etch stop layer 115 may be disposed on the insulating layer 113. In such a case, the capacitor lower electrodes 120 may penetrate the etch stop layer 115. The etch stop layer 115 may be formed of a silicon nitride (SiN) layer.

The substrate 110 may include a silicon substrate, a silicon-on-insulator (SOI) substrate, a silicon germanium (GeSi) substrate, a gallium arsenide (GaAs) substrate, a ceramic substrate, a quartz substrate or other suitable substrates. Each of the contact plugs 111 may include a polysilicon layer or a metallic conductive layer, and top surfaces of the contact plugs 111 may be covered with a barrier metal layer such as a titanium (Ti) layer or a composite layer of titanium (Ti) topped with titanium nitride (TiN).

Each of the capacitor lower electrodes 120 may include one of a metal nitride layer, a metal layer and a combination thereof. For example, each of the capacitor lower electrodes 120 may include at least one of a titanium nitride (TiN) layer, a ruthenium (Ru) layer, a tantalum nitride (TaN) layer, a tungsten nitride (WN) layer, a platinum (Pt) layer and an iridium (Ir) layer. The capacitor lower electrodes 120 may have a high aspect ratio, as illustrated in FIGS. 12A and 12B. For example, each of the capacitor lower electrodes 120 may have an aspect ratio of about 10 to about 30. As examples of the dimensions of the capacitor lower electrodes 120, the width (outer diameter) of each capacitor lower electrode 120 may be within the range of about 20 nanometers to about 100 nanometers and the height of each capacitor lower electrode 120 may be within the range of about 500 nanometers to about 4000 nanometers. However, these are just examples and the width and the height of each capacitor lower electrode 120 are not limited to being within the aforementioned numerical ranges.

Since each of the capacitor lower electrodes 120 has a high aspect ratio, it is easy to be tilted or collapsed during formation. Therefore, the semiconductor structure 10 further includes a supporting structure layer 130 directly contacting the top and a portion of the sidewalls of each capacitor lower electrode 120. The supporting structure layer 130 can help to fix the lower capacitor lower electrodes 120 to prevent them from tilting or collapsing. In order to remove the interlayer dielectric layer 114 and form a capacitor upper electrode or the like in a subsequent step, the supporting structure layer 130 has a plurality of openings 132 (only one opening is shown in FIG. 1). In other words, a portion of the interlayer dielectric 114 is not covered by the supporting structure layer 130. As shown in FIG. 1, a region between adjacent capacitor lower electrodes 120 and not covered by the supporting structure layer 130 is defined as the position of the opening 132.

In the subsequent steps, as shown in FIG. 2, the interlayer dielectric 114 is removed by an etching step, at this step, the capacitor lower electrodes 120 are supported by the supporting structure layer 130, and the plurality of openings 132 of the supporting structure layer 130 are exposed. Next, as shown in FIG. 3, an insulating layer 122 and the capacitor upper electrode 124 are formed over the capacitor lower electrode 120 to complete the main structure of the capacitor structure. It should be noted that the shape of the different openings 132 or the arrangement of the openings 132 will affect the structural strength of the supporting structure layer 130 supporting the lower electrodes 120 and the efficiency of removing the interlayer dielectric 114. Therefore, by adjusting different opening shapes and opening arrangements, a stronger supporting effect and faster efficiency for removing the interlayer dielectric can be achieved. The following paragraphs will discuss the shape of the opening and the arrangement of the openings in different embodiments of the present invention, and the remaining components (for example, the insulating layer 122 and the capacitor upper electrode 124) are omitted.

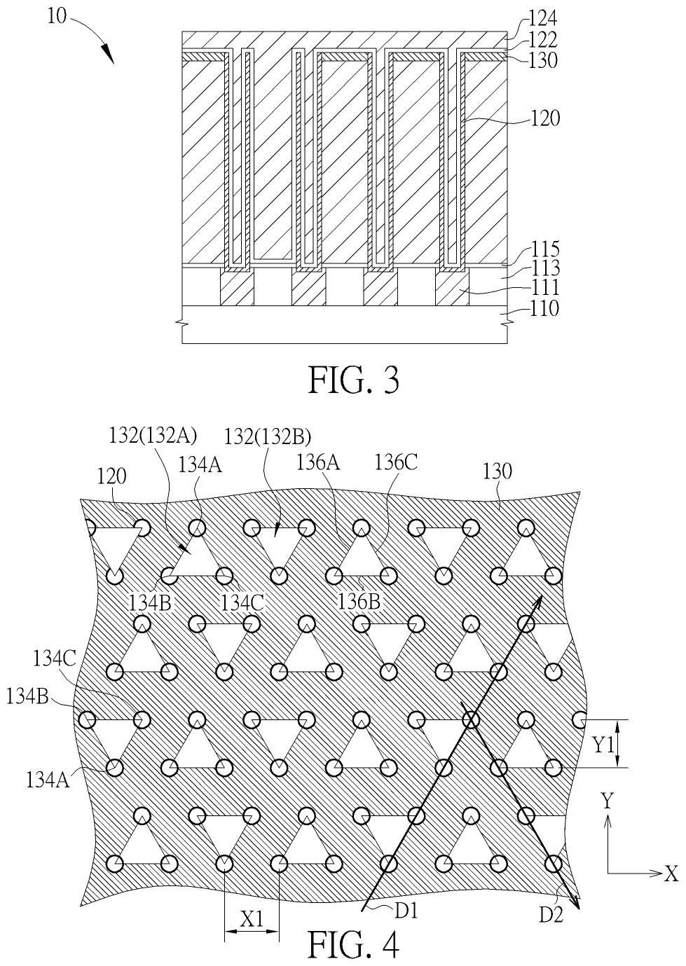

FIG. 4 is a top plan view showing the semiconductor structure of the first preferred embodiment of the present invention. To simplify the drawing, only the capacitor lower electrode 120, the supporting structure layer 130, and the opening 132 included in the supporting structure layer 130 are illustrated in FIG. 4. The remaining components such as the substrate, the contact structures, and the like are omitted. As shown in FIG. 4, in the present invention, each of the capacitor lower electrodes 120 is arranged in a diamond array. More specifically, each of the capacitor lower electrodes 120 is arranged along a first direction D1 and a second direction D2, the first direction D1 and the second direction D2 are not perpendicular to each other, so the capacitor lower electrodes 120 are not arranged in a rectangular array, but arranged in a diamond-shaped array. The supporting structure layer 130 includes openings 132. In this embodiment, each opening 132 is a triangular shape opening. The three corners of each of the openings 132 overlap with three adjacent capacitor lower electrodes 120 respectively. In more detail, any of the openings 132 has three corners defined as 134A, 134B, and 134C respectively, and three sides defined as 136A, 136B, and 136C respectively. From the top view, each of the corners 134A, 134B, and 134C overlaps with one of the capacitor lower electrodes 120, and each of the sides 136A, 136B, and 136C partially overlaps two adjacent lower electrodes 120 respectively.

In addition, the number and arrangement of the openings 132 are not limited in this embodiment, and the openings 132 of each triangle may include an isosceles triangle, an equilateral triangle (for example, the opening 132A in FIG. 4) or an inverted triangle (for example, the opening 132B in FIG. 4) and the like, the distance between the openings 132 can also be adjusted according to actual requirements. For example, taking the horizontal direction (X direction) as an example, the distance between two adjacent capacitor lower electrodes 120 is defined as a horizontal unit length X1. In this embodiment, the horizontal distance between the centers of two adjacent openings 132 is equivalent to X1. However, the invention is not limited thereto, and in other embodiments, the horizontal distance between two adjacent openings 132 may be equivalent to a multiple of X1. Similarly, from the vertical direction (Y direction), the distance between two adjacent capacitor lower electrodes 120 is defined as a vertical unit length Y1. In the present embodiment, the vertical distance between the centers of the two adjacent openings 132 is equivalent to Y1. However, the invention is not limited thereto, and in other embodiments, the vertical distance between two adjacent openings 132 may be equivalent to a multiple of Y1.

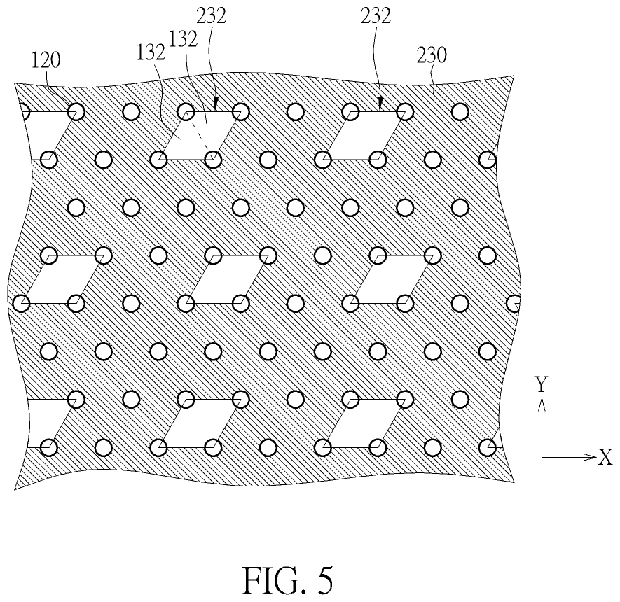

In other embodiments of the present invention, the capacitor lower electrode 120 also arranged in a diamond array, and thus detailed description thereof will not be repeated. However, the shape of the opening included in the supporting structure layer may be changed, for example, the triangular openings 132 may be combined with each other into openings of other shapes. FIG. 5 is a top plan view showing a semiconductor structure in accordance with a second preferred embodiment of the present invention. As shown in FIG. 5, the supporting structure layer 230 includes a plurality of openings 232, each of the openings 232 is an isosceles quadrilateral, and each of the quadrilateral openings 232 is combined by two triangular openings 132 (please refer to FIG. 4). Similarly, this embodiment does not limit the arrangement of the openings 232. In this embodiment, the horizontal distance between two adjacent openings 232 is 2X1, and the vertical distance between two adjacent openings 232 is 2Y1. However, it should be understood that the present invention is not limited thereto, and the horizontal distance and the vertical distance between the openings may be adjusted according to actual requirements. Regarding the definition of the horizontal unit length X1 and the vertical unit length Y1, please refer to FIG. 4, and details are not described herein again.

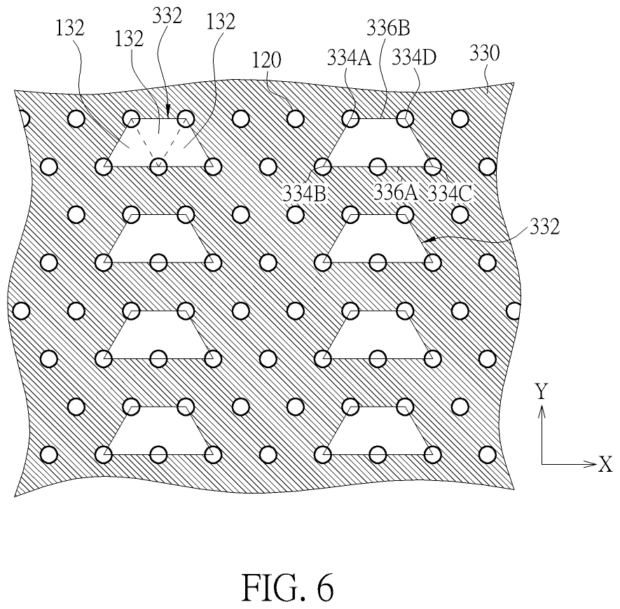

FIG. 6 is a top plan view showing a semiconductor structure in accordance with a third preferred embodiment of the present invention. As shown in FIG. 6, the supporting structure layer 330 includes a plurality of openings 332, each of the openings 332 is an isosceles trapezoid, and each of the trapezoidal openings 332 is combined by three triangular openings 132 (please refer to FIG. 4). Additionally, in the present embodiment, the isosceles trapezoidal opening 332 includes four corners 334A, 334B, 334C, and 334D, each of the corners 334A, 334B, 334C, and 334D overlaps a different capacitor lower electrode 120 respectively. In addition, each isosceles trapezoidal opening 332 includes a longer bottom edge 336A and a shorter top edge 336B, the bottom edge 336A partially overlaps three of the capacitor lower electrodes 120, and the top edge 336B partially overlaps two of the capacitor lower electrodes 120. Similarly, the embodiment does not limit the arrangement of the openings 332. In this embodiment, the horizontal distance between two adjacent openings 332 is 2X1, and the vertical distance between two adjacent openings 332 is Y1. However, it should be understood that the present invention is not limited thereto, and the horizontal distance and the vertical distance between the openings may be adjusted according to actual requirements.

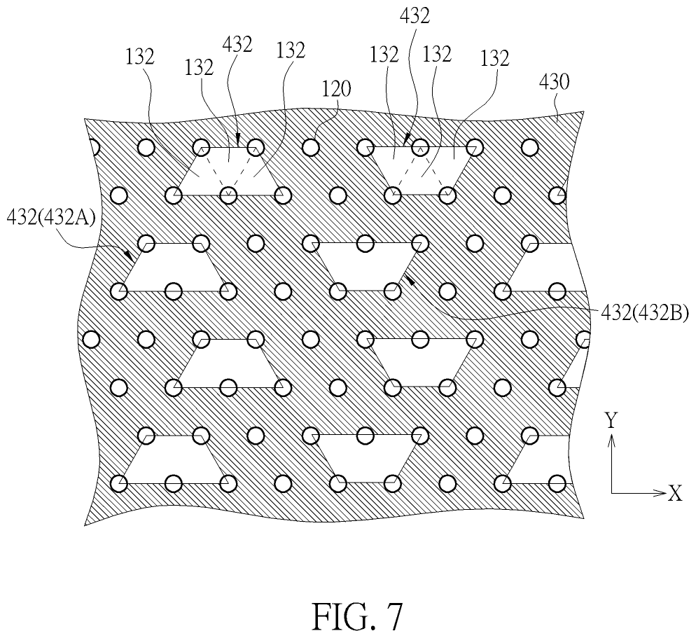

FIG. 7 is a top plan view showing a semiconductor structure in accordance with a fourth preferred embodiment of the present invention. As shown in FIG. 7, the supporting structure layer 430 includes a plurality of openings 432, each of the openings 432 is an isosceles trapezoid, and each of the trapezoidal openings 432 is combined by three triangular openings 132 (please refer to FIG. 4). In addition, the present embodiment is different from the above-described third embodiment in that the isosceles trapezoidal opening in the embodiment includes a plurality of isosceles trapezoidal openings (such as the opening 432A in FIG. 7) and a plurality of inverted isosceles trapezoidal openings (such as opening 432B in FIG. 7). That is, the shape of the inverted isosceles trapezoidal opening 432B after being rotated 180 degrees along the XY plane will be the same as the shape of the isosceles trapezoidal opening 432A. Preferably, in the present embodiment, from the horizontal direction (X-axis), the isosceles trapezoidal openings and the inverted isosceles trapezoidal openings are alternately arranged, and number of the isosceles trapezoidal openings and number of the inverted isosceles trapezoidal openings included in the supporting structure layer 430 are approximately the same (evenly distributed). As a result, the overall isosceles trapezoidal openings 432 will be evenly distributed on the supporting structure layer 430, to achieve an overall uniform supporting force. Similarly, the embodiment does not limit the arrangement of the openings 432. In this embodiment, the horizontal distance between two adjacent openings 432 is 2X1, and the vertical distance between two adjacent openings 432 is Y1. However, it should be understood that the present invention is not limited thereto, and the horizontal distance and the vertical distance between the openings may be adjusted according to actual requirements.

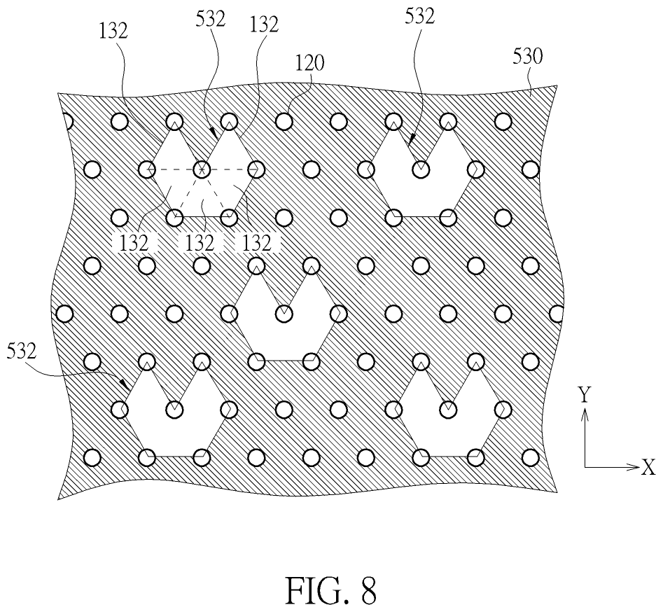

FIG. 8 is a top plan view showing a semiconductor structure in accordance with a fifth preferred embodiment of the present invention. As shown in FIG. 8, the supporting structure layer 530 includes a plurality of openings 532, each of the openings 532 is a heptagon opening, and each of the heptagonal openings 532 is composed of five triangular openings 132 (please Refer to FIG. 4). Similarly, the embodiment does not limit the arrangement of the openings 532. The horizontal distance and the vertical distance between the openings can be adjusted according to actual requirements.

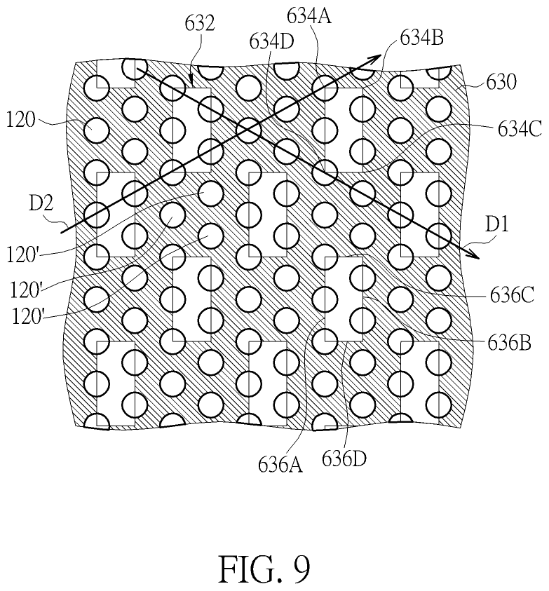

In other embodiments of the present invention, please refer to FIG. 9, which is a plan top view of a semiconductor structure in accordance with a sixth preferred embodiment of the present invention. As shown in FIG. 9, the supporting structure layer 630 includes a plurality of openings 632. In this embodiment, each opening 632 is rectangular and has four corners 634A, 634B, 634C and 634D, two long sides 636A, 636B and two short sides 636C and 636D. Two of the corners (e.g., 634A and 634B) overlap the capacitor lower electrodes 120, while the other two corners (e.g., 634C and 634D) do not overlap the capacitor lower electrode 120. In addition, the long side 636A partially overlaps three of the capacitor lower electrodes 120, the long side 636B partially overlaps two of the capacitor lower electrodes 120, and the short side 636C or the short side 636D partially overlaps with one of the capacitor lower electrodes 120.

In addition, three capacitor lower electrodes 120′ that are not overlapped with the openings 632 are disposed between every two adjacent openings 632, and the three capacitor lower electrodes 120′ are arranged in a triangular shape instead of being arranged in a straight line. Furthermore, for all the openings 632 included in the supporting structure layer 630, the long sides (for example, the long sides 636A) partially overlapping three capacitor lower electrodes 120 are located on the same side, for example, as shown in FIG. 9, the long sides 636A partially overlapping three capacitor lower electrodes 120 are close to a negative side of the X-axis (−X direction). In contrast, all of the long sides 636B partially overlapping two capacitor lower electrodes 120 are close to a positive side of the X-axis (+X direction). By this arrangement, all of the openings 632 on the supporting structure layer 630 will be evenly distributed to achieve a uniform supporting force.

In summary, the present invention provides a semiconductor structure having cylindrical capacitor electrodes and a supporting structure layer. The supporting structure layer comprises openings of different shapes and different arrangements. In the present invention, by changing the shape and arrangement of the openings, to achieve the uniform effect of the overall force of the supporting structure layer.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor structure, comprising:
a substrate comprising a plurality of capacitor lower electrodes, wherein the capacitor lower electrodes are arranged in a diamond array along a first direction and a second direction respectively, and wherein the first direction and the second direction are not perpendicular to each other; and
a supporting structure layer contacting at least parts of the capacitor lower electrodes, wherein the supporting structure layer comprises a plurality of triangular openings, and wherein the three corners of each triangular opening are overlapped with three adjacent capacitor lower electrodes respectively.

2. The semiconductor structure of claim 1, wherein the shape of the triangular opening comprises an isosceles triangle or an equilateral triangle.

3. The semiconductor structure of claim 2, wherein the triangular opening comprises three sides, and each side overlaps only two of the capacitor lower electrodes.

4. The semiconductor structure of claim 1, further comprising a plurality of isosceles quadrilateral openings, wherein each of the isosceles quadrilateral openings is formed by combining two adjacent triangular openings.

5. The semiconductor structure of claim 1, further comprising a plurality of isosceles trapezoidal openings, wherein each of the isosceles trapezoidal openings is formed by combining three adjacent triangular openings.

6. The semiconductor structure of claim 5, wherein each isosceles trapezoidal opening comprises a longer bottom edge and a shorter top edge, and the top edge partially overlaps with two of the capacitor lower electrodes, the bottom edge partially overlaps with three of the capacitor lower electrodes.

7. The semiconductor structure of claim 6, further comprising two triangular openings that contact the bottom edge of the isosceles trapezoidal opening directly and combined into a heptagon opening.

8. The semiconductor structure of claim 5, wherein the isosceles trapezoidal opening comprises at least one isosceles trapezoidal opening and at least one inverted isosceles trapezoidal opening, wherein the shape of the inverted isosceles trapezoidal opening is same as the shape of the isosceles trapezoidal opening after rotating 180 degrees along an XY plane.

9. The semiconductor structure of claim 8, wherein the isosceles trapezoidal opening and the inverted isosceles trapezoidal opening are alternately arranged along an X-axis direction.

10. A semiconductor structure, comprising:
a substrate comprising a plurality of capacitor lower electrodes, wherein the capacitor lower electrodes are arranged in a diamond array along a first direction and a second direction respectively, and wherein the first direction and the second direction are not perpendicular to each other; and
a supporting structure layer contacting at least parts of the capacitor lower electrodes, wherein the supporting structure layer comprises a plurality of isosceles trapezoidal openings, and wherein the four corners of each isosceles trapezoidal openings are overlapped with four different capacitor lower electrodes respectively.

11. The semiconductor structure of claim 10, wherein the isosceles trapezoidal opening comprises at least one isosceles trapezoidal opening and at least one inverted isosceles trapezoidal opening, wherein the shape of the inverted isosceles trapezoidal opening is same as the shape of the isosceles trapezoidal opening after rotating 180 degrees along an XY plane.

12. The semiconductor structure of claim 11, wherein the isosceles trapezoidal opening and the inverted isosceles trapezoidal opening are alternately arranged along an X-axis direction.

13. The semiconductor structure of claim 12, wherein along the X-axis direction, the horizontal distance between any two adjacent capacitor lower electrodes is defined as X1, and the distance between any of the isosceles trapezoidal openings and the adjacent inverted isosceles trapezoidal opening is 2X1.

14. The semiconductor structure of claim 11, wherein the isosceles trapezoidal openings and the inverted isosceles trapezoidal openings are evenly distributed on the XY plane.

15. The semiconductor structure of claim 10, wherein the supporting structure layer only comprises isosceles trapezoidal openings.

16. The semiconductor structure of claim 15, wherein along a Y-axis direction, the vertical distance between any two adjacent capacitor lower electrodes is defined as Y1, and the distance between two adjacent isosceles trapezoidal openings is Y1.

17. The semiconductor structure of claim 10, wherein each isosceles trapezoidal opening comprises a longer bottom edge and a shorter top edge, and the top edge partially overlaps with two of the capacitor lower electrodes, the bottom edge partially overlaps with three of the capacitor lower electrodes.

18. A semiconductor structure, comprising:
a substrate comprising a plurality of capacitor lower electrodes, wherein the capacitor lower electrodes are arranged in a diamond array along a first direction and a second direction respectively, and wherein the first direction and the second direction are not perpendicular to each other; and
a supporting structure layer contacting at least parts of the capacitor lower electrodes, wherein the supporting structure layer comprises a plurality of rectangular openings, and three capacitor lower electrodes that do not overlap the rectangular openings are disposed between any two adjacent rectangular openings, wherein the three capacitor lower electrodes are not arranged in a straight line.

19. The semiconductor structure of claim 18, wherein each of the rectangular openings comprises a first long side, a second long side, and two short sides, the first long side partially overlaps with three of the lower capacitor electrodes, the second long side partially overlaps with two of the capacitor lower electrodes, and the short side partially overlap with one of the capacitor lower electrodes.

20. The semiconductor structure of claim 19, wherein a X-axis is defined, and all the first long sides of the rectangular openings are close to a negative side of the X-axis, and all the second long sides of the rectangular openings are close a positive side of the X-axis.
